(19) United States
(12) Patent Application Publication
(10) Pub. No.: US 2007/0158789 A1
(43) Pub. Date: Jul. 12, 2007

(54) Material comprising predetermined number of atomic layers and method for manufacturing predetermined number of atomic layers

(76) Inventor: Sadeg M. Faris, Pleasantville, NY (US)

Correspondence Address: REVEO, INC., 3 WESTCHESTER PLAZA, ELMSFORD, NY, 10523, US

(21) Appl. No.: 11/496,059

(22) Filed: Jul. 28, 2006

Related U.S. Application Data
(63) Continuation-in-part of application No. 10/582,605.
(60) Provisional application No. 60/669,029, filed on Apr. 7, 2005.
(60) Provisional application No. 60/699,619, filed on Jul. 15, 2005.

(51) Int. Cl. H01L 23/58

(52) U.S. Cl. 257/635

(57) ABSTRACT

The present invention relates to a composition of matter based on lamellar materials, and method of deriving one or more predetermined number of layers of material from a bulk lamellar material. In one aspect of the present invention, a material comprising a predetermined number of one or more layers is provided. The one or more layers are layers of a lamellar material that are weakly bonded to each other. In further aspects of the present invention, methods are provided for forming a predetermined number of layers of a lamellar material.

### RELATED APPLICATIONS

This application is a Continuation in Part of U.S. Non-provisional application Ser. No. 10/582,605 filed on Jun. 9, 2006, which is a national phase filing under 35 USC 371 of PCT application Ser. No., 06/13681 filed on Apr. 7, 2006, entitled “Probes, Methods of Making Probes and Applications of Probes”, which claims priority to U.S. Provisional Application Nos. 60/669,029 filed on Apr. 7, 2005 entitled “DNA Sequencing Method and System” and 60/699,619 filed on Jul. 15, 2005 entitled “Molecular Analysis Probe, Systems and Methods, including DNA Sequencing”, and is related to U.S. Non-provisional 11/______ ,filed on the same date as the present application, under Express Mail Label Number EV443782141US (Attorney Docket Number REVEO-0260USAAPN39), entitled “Method Of and System For Cutting Carbon Based Materials”, and U.S. Non-provisional 11/______, filed on the same date as the present application, under Express Mail Label Number EV443782138US (Attorney Docket Number REVEO-0260USAAPN40), entitled “Method of and System For Forming Nanostructures and Nanotubes” all of which are incorporated by reference herein.

### TECHNICAL FIELD

The present invention relates to a composition of matter based on lamellar materials, and method of deriving one or more predetermined number of layers of material from a bulk lamellar material.

### BACKGROUND ART

Twenty-first century science and technology endeavors, research and development innovations that solve problems for man-kind will increasingly be dominated by the ability to make structures and objects that have sizes with length scales approaching those of atoms and molecules having dimensions of a nano-meter or less. Nano-scale matter and objects exhibit unique behaviors, some of which have yet to be revealed in addition to the known remarkable optical, thermal, electrical and mechanical properties. These open new vistas for many applications. For example, sequencing, imaging, nano-lithography, manipulation, nano-scale self assembly, nanometer scale chemistry, and many other applications with benefit from nano-scale technology development.

It is envisioned and believed that being involved in the nano-size frontier of science, technology and innovation is a sure path to regional and national economic well being, and competitiveness. This is evidenced by the extraordinary investment activities by big and small countries, large and small private sector enterprises and nearly unparalleled entrepreneurial activities.

To advance in the nano-scale frontier science and technology requires access to and mastering the following:
Tools to produce nano-objects
Tools to measure sizes with sub-Angstrom precision
Substrates that have atomic smoothness with minimum contamination
Tools to see (image) nano-objects and manipulate them, grabbing, moving, gluing, etc.
Nano funnels nozzles probes for dispensing substances and stimuli
Tools to accurately measure all physical properties such as thermal, electrical, and optical.

Key parameters become smaller by 10 to 20 orders of magnitude as compared to similar parameters in the macro-world. In the last 5 years the collective achievements of the best and brightest people around the world related to the above tools have grown at astonishing rates, delivering numerous discoveries, innovations, methods, products and tools.

Known techniques allow production of sub-micron objects and features that can be produced by means of conventional optical, UV, e-beam, X-ray and lithography. These tools are being extended to produce sizes below 30 nanometers. As they are stretched to produce even smaller sizes, their limitations become more and more apparent, in terms of cost, foot-print, etc. Indeed, at high electron and ion beam accelerating voltages >100KV features smaller that 10 nm have been demonstrated. The preparation steps and the cost of the equipment and ancillary components make these prior art methods cumbersome and slow.

Various embodiments presented in parent application Ser. No. 10/582,605 (and related PCT application Ser. No., 06/13681), incorporated by reference herein, depart from use of convention lithography based photon, ion and e-beams to produce the smallest features. Instead, ultra-thin films are used in parent application Ser. No. 10/582,605 for this purpose thereby allowing one to produce similar or better results with faster ramp-up times and with more convenience.

There are many known methods of producing films with atomic precision. These include, deposition by sputtering, electron beam, ion beam, molecular beam epitaxy, CVD, MOCVD, plasma, laser deposition, pyrolitic deposition, electrochemical, thermal evaporation, sputtering, electro-deposition, molecular beam epitaxy, adsorption from solution, Langmuir-Blodgett (LB) technique, self-assembly and many other related methods collectively referred to as Thin Film Deposition Methods. Accurate metrology enables the production and control of thicknesses with Angstrom precision. Producing free standing films by peeling is possible as taught in U.S. Pat. No. 7,045,878 and U.S. patent application Ser. No. 10/970,814 filed on Oct. 21, 2004 and manipulation and formation of vertically integrated devices of such films taught in applicant's U.S. Pat. No. 7,033,910, U.S. patent application Ser. No. 11/406,848, U.S. patent No. 6,875,671, U.S. patent application Ser. No. 11/020,753, U.S. patent application Ser. No. 10/719,663, U.S. patent No. 6,956,268, and U.S. patent application Ser. No. 10/793,653, all of which are incorporated by reference herein.

The advent of scanning tunneling microscopy (STM), atomic force microscopy, AFM, scanning probe microscopy, SPM, and related tools have enabled the imaging of surfaces and structures with atomic resolution. This has opened new avenues to advance our understanding of many physical and chemical phenomena that are being exploited in numerous practical applications in the fields of medicine, nanotechnology, nano-electronics, genomics, proteomics, nano-electrochemistry, and destined to make even more contributions in other fields in the futures.

To achieve nano-scale resolution and nanofabrication accuracy, and to properly interpret physical and chemical phenomena, it is desirable and oftentimes necessary to use atomically flat, atomically smooth substrates over a large area, for instance in the range of several square microns to several square centimeters. To produce such substrates, conventional methods rely on unsophisticated and inaccurate techniques of attaching an adhesive tape to the surface of mica or graphite to peel the top most atomic layers to reveal a fresh atomically smooth surface of a piece of mica or graphite of size and thickness. In almost all situations the atomic surface is the desired result while the lateral shape or size or thickness is of little importance. Conventional techniques could not teach methods of producing, handling and manipulating samples having a single layer of graphite (also called graphene) or mica, for example, or a predetermined desired number of mono-atomic of mica or graphite layers.

Graphites are well known and are widely used materials. For example U.S. Pat. No. 6,538,892 exploits its good mechanical and anisotropic thermal properties for the construction of heat sinks. Graphites according to the description in U.S. Pat. No. 6,538,892, are made up of layer planes of hexagonal arrays or networks of carbon atoms. These layer planes of hexagonally arranged carbon atoms are substantially flat and are oriented or ordered so as to be substantially parallel and equidistant to one another, as shown in FIG. 1. The substantially flat, parallel equidistant sheets or layers of carbon atoms, 110, usually referred to as graphene layers or basal planes, are linked or bonded together and groups thereof are arranged in crystallites. Highly ordered graphites consist of crystallites of considerable size: the crystallites being highly aligned or oriented with respect to each other and having well ordered carbon layers. In other words, highly ordered graphites have a high degree of preferred crystallite orientation. It should be noted that graphites possess anisotropic structures and thus exhibit or possess many properties that are highly directional e.g. thermal and electrical conductivity and fluid diffusion.

Briefly, graphites may be characterized as laminated structures of carbon, that is, structures consisting of superposed layers of carbon atoms joined together by weak van der Waals forces 112. In considering the graphite structure, two axes or directions are usually noted, to wit, the “c” axis or direction and the “a” axes or directions. For simplicity, the “c” axis or direction may be considered as the direction perpendicular to the carbon layers. The “a” axis or directions may be considered as the directions parallel to the carbon layers or the directions perpendicular to the “c” direction. The graphites suitable for manufacturing flexible graphite sheets possess a very high degree of orientation.

The bonding forces holding the parallel layers of carbon atoms together are only weak van der Waals forces. In a process referred to as exfoliation of graphite, natural graphites can be treated so that the spacing 112, d, in FIG. 1A between the superposed carbon layers 110 can be appreciably opened up so as to provide a marked expansion of Nd, as in FIG. 1B, the direction perpendicular to the layers, that is, in the “c” direction, and thus forms an expanded graphite structure in which the laminar character of the carbon layers is substantially retained. It has been shown that N can be in the range of 100 to 1000 according to the treatment process. The graphite layers are referred to as graphene layers possess very high electrical and thermal conductivities exceeding those of copper, while retain high temperatures and exceedingly Young modulus.

Recently, Andrei Geim and colleagues of the University of Manchester isolated a single sheet of graphene and measured its remarkable properties which include conductivity 100 higher than copper and astonishing Quantum Hall Effect behavior. These and other results are described in January, 2006 , Physics Today. These results could be made possible only after successful isolation of a single 1 Angstrom graphene layer, a feat that was not previously possible. Geim's team succeeded in isolating a single graphene layer by random, tedious and unpredictable method.

According to the Physics Today Article:

“Their method is astonishingly simple: Use adhesive tape to peel off weakly bound layers from a graphite crystal and then gently rub those fresh layers against an oxidized silicon surface. The trick was to find the relatively rare monolayer flakes among the macroscopic shavings. Although the flakes are transparent under an optical microscope, the different thicknesses leave telltale interference patterns on the SiO2, much like colored fringes on an oily puddle. The patterns told the researchers where to hunt for single monolayers using atomic force microscopy.”

The work confirmed that graphene is remarkable—stable, chemically inert, and crystalline under ambient conditions.”

In another approach, a team led by Walt A. de Heer of the Georgia Institute of Technology in Atlanta produced graphene by heating the surface of a wafer of silicon carbide so that the silicon atoms evaporated, leaving behind a few layers of carbon atoms that assembled into graphene. As taught therein, a thin-film graphitic layer is produced by annealing preselected crystal face of a crystal.

In still another approach, Stankovich et al. derived exfoliated graphene oxide and attempted to reduce the graphene oxide to graphene, as an additive to enhance conductivity of graphene-polymer composites. Graphite oxides were chemically modified by treating graphite oxide with organic isocyanates to reduce the hydrophilic character of graphene oxide sheets. These isocyanate-derivatized graphite oxides form stable dispersions in polar aprotic solvents (such as N,N-dimethylformamide (DMF)), consisting of completely exfoliated, functionalized individual graphene oxide sheets with thickness 1 nm. These dispersions of isocyanate-derivatized graphite oxide allow graphene oxide sheets to be intimately mixed with many organic polymers to form graphene-polymer composites.

From the above and other recent investigations on graphene as well as from commercial supplier of graphite substrate, one concludes that there remains a need for inventing convenient, low cost, and fast methods for isolating single layers of graphene and predictable stacks of selected number of graphene layers. There further remains a need for methods for isolating single layer or predictable number of layers from lamellar or multilayer materials in general.

In addition to methods for isolating single layer or predictable number of layers from lamellar or multilayer materials in general, there remains a need to accurately form layers of graphene or other carbon based materials into virtually any desired shape to fit the application, for example, as a nanotool or component of a nanotool.

Conventional approaches to shaping and cutting on a nanoscale level, particularly cutting ultra thin (e.g., single atomic layer) are limited. Conventional cutting techniques, for example, those based on laser cutting, water jet, mechanical cutting tools, plasma cutting, or chemical etching exist, but have limitations as to the ability to control the cut depth in a convenient manner.

U.S. Pat. No. 6,869,581 teaches “cutting” by globurization of a deposited metal after pretreatment including heating the deposited metal close to its melting point in an oxygen atmosphere to induce oxidation.

With the advent of nanoscale materials and tools, a need exists for a suitable method to cut or define features of atomic layers of material, such as layers of graphene. However, using conventional approaches, it is not possible to cut to a selected depth (e.g., cut only one layer or to a selected depth of a multilayer structure). Furthermore, to minimize or avoid the need for post-cutting processing operations, for example, to remove defects and the like, cutting operations should not be detrimental to the material characteristics. Therefore, a need remains for efficient and accurate methods and systems for cutting or defining features within atomic layers of material.

### OBJECTS AND BRIEF SUMMARY OF THE INVENTION

Embodiments of the present invention described herein teach new methods, devices and tools that advances the nanotechnology art listed above. By departing from methods of prior art and adding new techniques departing form the teaching of the prior art, embodiments of the present invention provide the ability to make free standing nano-thickness atomically smooth films, including single or multiple layers from layered or lamellar materials including but not limited to such as mica, WS2, super lattices, MoS2, YBCO (yttrium barium copper oxide) and other related superconductors, NbSe2, Bi2Sr2CaCu2Ox, graphite, boron nitride, dichalcogenide, trichalcogenide, tetrachalcogenide, pentachalcogenide, double hydroxides, anionic clays and hydrotalcite-like materials. These single or multiple layers can be used as substrates and or components for nanotools, and as starting materials for use to create unique composite materials of many different types of compositions and configurations.

Accordingly, certain objects herein are to produce single or predetermined numbers of known mono-atomic layers of graphene, mica and other layered or lamellar materials such as WS2, super lattices, MoS2, YBCO (yttrium barium copper oxide) and other related superconductors, NbSe2, Bi2Sr2CaCu2Ox, graphite, boron nitride, dichalcogenide, trichalcogenide, tetrachalcogenide, pentachalcogenide, double hydroxides, anionic clays and hydrotalcite-like materials, conveniently and inexpensively. Another object of this aspect of the invention to separate or exfoliate single mono-atomic layers from layered or lamellar materials including but not limited to layers of graphene and other lamellar or layered material derivative, and attaching them to substrate through a releasable bond.

In one aspect of the present invention, a material comprising a predetermined number of one or more layers is provided. The one or more layers are layers of a lamellar material that are weakly bonded to each other. In contrast to conventional processing of lamellar materials such as graphite, where random numbers of graphene layers are attempted to be derived from graphite, in the material according to aspects of the present invention, predetermined numbers of layers are provided.

In another aspect of the present invention, the predetermined number of layers are at least partially supported by a substrate.

In another aspect of the present invention, the predetermined number of layers are permanently attached to at least a portion of a substrate.

In another aspect of the present invention, the predetermined number of layers are removably attached to least a portion of a substrate.

In another aspect of the present invention, the at least one layer is an atomic layer of carbon atoms.

In another aspect of the present invention, the layer is a layer of graphene.

In another aspect of the present invention, at least a portion of a surface of said material is atomically flat.

In another aspect of the present invention, the at least one predetermined number of layers comprises a plurality a layers, wherein said plurality of layers is exfoliated.

In another aspect of the present invention, a composite material is provided including the material comprising a plural predetermined number of one or more layers and at least one introduced atomic or molecular species. In certain embodiments, the introduced atomic or molecular species is present at predefined depths between one or more of said plural layers. In certain other embodiments, the introduced atomic or molecular species is present at random depths between one or more of said plural layers. In certain further embodiments, the introduced atomic or molecular species is present at predefined areas of said material.

In another aspect of the present invention, a composite material is provided including the material comprising a predetermined number of one or more layers at least one layer of another material.

In another aspect of the present invention, a composite material is provided including a predetermined number layers of a first material layered with a predetermined number layers of a second material. In certain embodiments, the composite material further includes at least one introduced atomic or molecular species. In certain other embodiments, the introduced atomic or molecular species is present at random depths between one or more of said plural layers. In certain further embodiments, the introduced atomic or molecular species is present at predefined areas of said material.

In further aspects of the present invention, methods are provided for forming a predetermined number of layers of a lamellar material.

In one aspect of the present invention, a method of deriving a predetermined number of layers of a lamellar material includes permanently or removably attaching a substrate to a surface of a lamellar material having a plurality of layers that are weakly bonded to each other and applying a mechanical force at an edge between adjacent or non-adjacent layers with a tool having a knife edge configuration and a suitable tip edge thickness (e.g., sharpness).

In another aspect of the present invention, a method of deriving a predetermined number of layers of a lamellar material includes permanently or removably attaching a substrate to a surface of a lamellar material having a plurality of layers that are weakly bonded to each other, and applying a mechanical force between terminal ends with a tool having a knife edge configuration and a suitable tip edge thickness (e.g., sharpness). In further embodiments of this method, a mechanical force is also applied between terminal ends at another location of the layers with a tool having a knife edge configuration a suitable tip edge thickness (e.g., sharpness).

In another aspect of the present invention, a method of deriving a predetermined number of layers of a lamellar material includes permanently or removably attaching a substrate to a surface of a lamellar material having a plurality of layers that are weakly bonded to each other. The lamellar material is provided with a first layer having a first terminal end with an exposed face facing in a first direction and a second layer having a first terminal end in step configuration with the first terminal end of the first layer. Additionally, the first layer further including a second terminal end and the second layer further including a second terminal end with an exposed face, the first terminal ends being in a step configuration. A mechanical force is applied toward the exposed face of the second layer in a direction generally opposite the substrate thereby lifting off the predetermined number of layers. In certain other embodiments of this method, a mechanical force is also applied toward the exposed face of said first layer in a direction generally toward the substrate., so as to provide a “twits” lift-off action.

In another aspect of the present invention, a method of deriving a predetermined number of layers of a lamellar material includes applying a current between an electrode on or within a substrate attached to a lamellar material and a selected layer of the lamellar material, so as to create separation force whereby the interlayer forces between the selected layer and an adjacent layer proximate are decreased. In a further embodiment of this method, interlayer forces between the selected layer and the adjacent layer are decreased sufficiently to cause physical separation. In still further embodiments of this method, a mechanical force is also applied to pull one or more predetermined number of layers.

In another aspect of the present invention, a method of deriving a predetermined number of layers of a lamellar material includes applying a voltage between one or more electrode on or within a substrate attached to the lamellar materials and a selected layer; so as to create a separation force whereby the interlayer forces between the selected layer and an adjacent are decreased. In a further embodiment of this method, interlayer forces between the selected layer and the adjacent layer are decreased sufficiently to cause physical separation. In still further embodiments of this method, a mechanical force is also applied to pull one or more predetermined number of layers.

In another aspect of the present invention, a method of deriving a predetermined number of layers of a lamellar material includes permanently or removably attaching a first substrate to a first surface of a lamellar material having a plurality of layers that are weakly bonded to each other, the first substrate attached with an attachment force greater than the interlayer forces of the lamellar material. A second substrate is also permanently or removably attaching a second substrate to a second surface of the lamellar material. The first substrate is lifted to separate one or more layers of the lamellar material from other layer or layers of the lamellar material attached to the second substrate. This process may be repeated until a predetermined number of atomic layers is derived.

### BRIEF DESCRIPTION OF THE FIGURES

The foregoing summary as well as the following detailed description of preferred embodiments of the invention will be better understood when read in conjunction with the appended drawings. For the purpose of illustrating the various embodiments and aspects of the invention, there is shown in the drawings embodiments which are presently preferred. It should be understood, however, that the invention is not limited to the precise arrangements and instrumentalities shown in the drawings, where:

FIG. 1A shows a representation of a lamellar or multilayer material such as graphite;

FIG. 1B shows a representation of a lamellar or multilayer material such as graphite whereby spacing between layers are expanded;

FIG. 2A shows one embodiment of a method step according to the present invention to selectively peel off a single layer from a lamellar material

FIGS. 2B-2C show one embodiment of a system and method according to the present invention to selectively peel off a single layer from a lamellar material;

FIGS. 2D-2F show another embodiment of a system and method according to the present invention to selectively peel off a single layer from a lamellar material;

FIGS. 3A-3C show another embodiment of a system and method according to the present invention to selectively peel off a single layer from a lamellar material;

FIGS. 4A-4B show another embodiment of a system and method according to the present invention to selectively peel off a single layer from a lamellar material;

FIGS. 5A-5B show another embodiment of a system and method according to the present invention to selectively peel off a single layer from a lamellar material;

FIGS. 6A-6C show another embodiment of a system and method according to the present invention to selectively peel off a single layer from a lamellar material;

FIG. 7 shows a heterogeneous lamellar structure including a predetermined numbers of atomic layers of various types of material;

FIGS. 8A-8C show various embodiments of a predetermined numbers of atomic layers having material incorporate between certain layers thereof and at various locations; and

FIGS. 9A-9C show a single layer, three layers and any number N layers of the lamellar material that may be derived according to certain aspects to the present invention;

### DETAILED DESCRIPTION OF THE FIGURES

Certain aspects of the present invention provides convenient, low cost, and fast methods for isolating single layers of graphene and predictable stacks of selected number of graphene layers. Methods for isolating single layer or predictable number of layers from lamellar or multilayer materials are also provided by certain aspects of the present invention. Lamellar or multilayer materials that may be used to isolate a single layer or a predictable number of layers include but are not limited to mica, WS2, super lattices, MoS2, YBCO (yttrium barium copper oxide) and other related superconductors, NbSe2, Bi2Sr2CaCu2Ox, graphite, boron nitride, dichalcogenide, trichalcogenide, tetrachalcogenide, pentachalcogenide, double hydroxides, anionic clays and hydrotalcite-like materials.

Therefore, many aspects of the present invention involve production of single and a predetermined number of multiple layers of lamellar material. Many of the inventive features and certain embodiments of the present invention rely on the ability to make ultra-thin, nano-scale films. In further embodiments, it is desirable that these films are atomically flat films. These enable the fabrication of all the probe configurations that perform a variety of functions necessary to advance the frontier of nano-science and technology including but not limited to imaging, analysis, sequencing, nano-lithography, and nano-manipulation as well a variety of other applications. Thin film deposition methods describe above may be used to produce thing films with Angstrom precision. Alternatively, even more precisely define thickness can be produced the controlled peeling of one or more predetermined number of layers from lamellar material as taught herein. These embodiments described herein apply to lamellar or multilayer materials, including but not limited to graphite to produce graphene layers, layers of mica, MoS2 and other lamellar or multilayer materials.

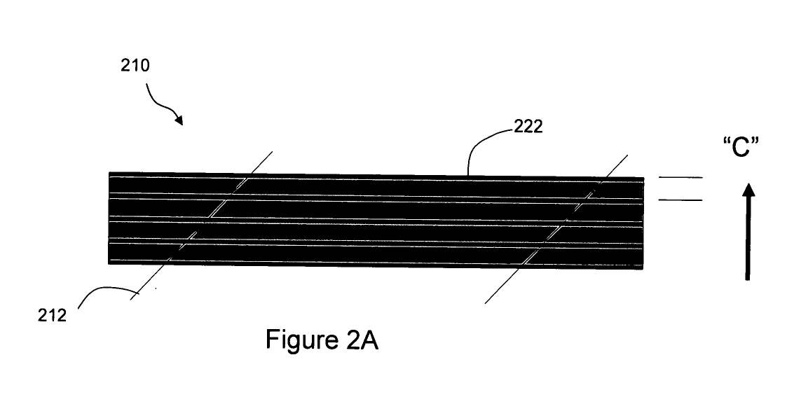

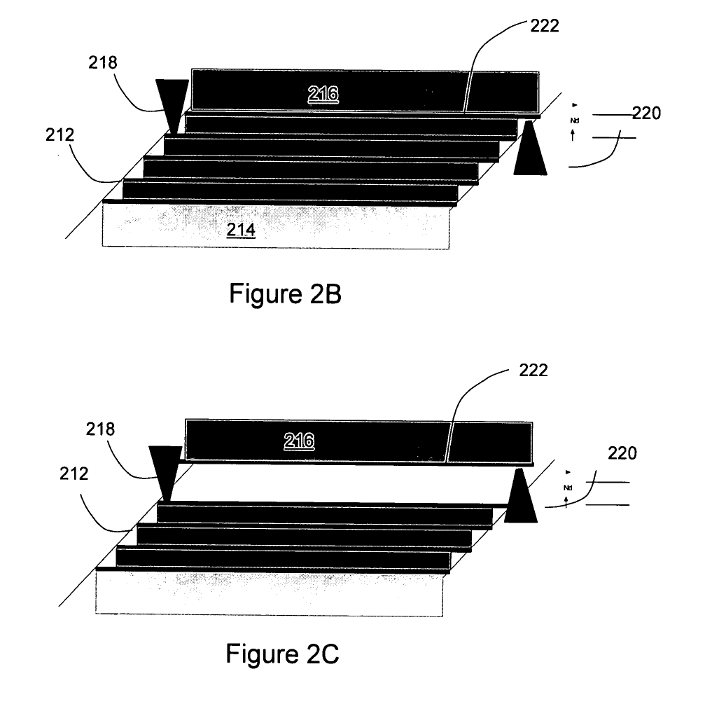

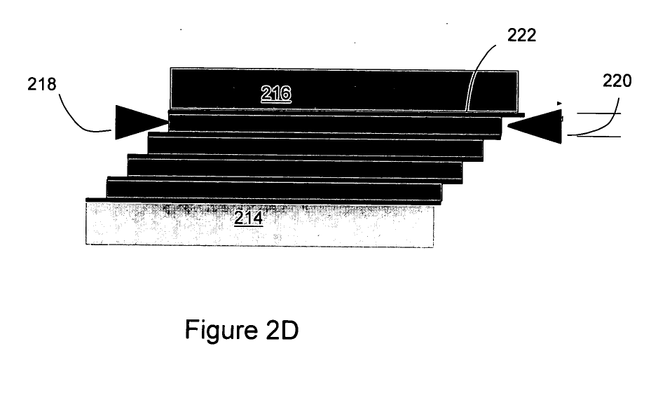

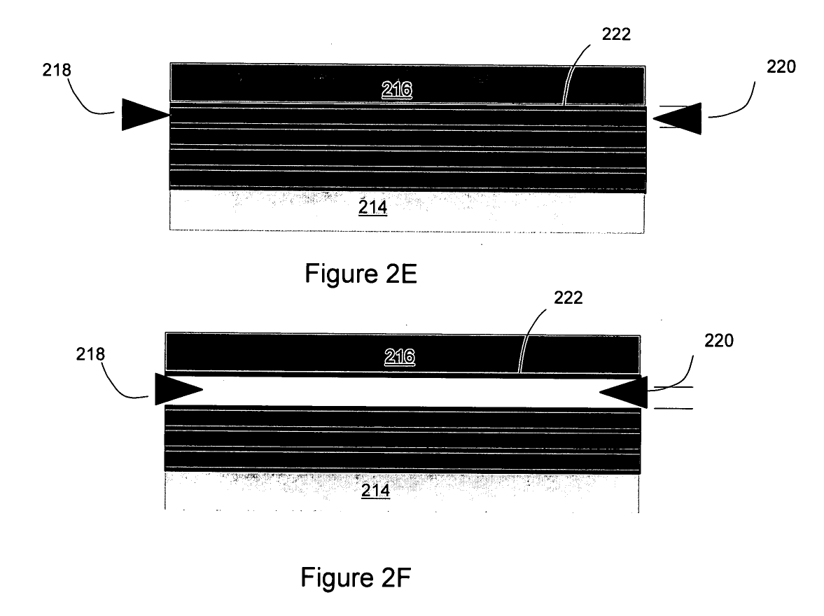

One embodiment to selectively peel off a single layer from a lamellar material, 210, is illustrated in FIG. 2A. The material is cut along the line 212, at an angle of, for example, 20 degrees or more relative the “c” axis. Such an angled cut allows access to the top most layer 222, as each layer is sequentially removed according to FIG. 2B. Two knife edge probes, as described in parent application Ser. No. 10/582,605 (and related PCT application Ser. No., 06/13681), incorporated by reference herein, for example, having tip opening dimensions small enough to access individual layers or groups of layers that are revealed due to the angular cut, are use to facilitate the peeling process. Knife edge probe 218 pushes down on the second layer (which is supported on other layers and or a first substrate 214) while knife edge probe 220, pushes up the first layer against a second substrate 216, attached to the desirable first layer. The substrate 216 may be permanently bonded or removably bonded to the first layer 222 Removable bonding may be accomplished by various bonding and handling techniques including but not limited to adhesives, waxes, and vacuum handlers. FIG. 2C shows the complete separation of the first layer that is attached to the substrate 216 which is being pulled vertically to facilitate the separation process.

In another embodiment, knife edges 218, 220, are applied in the horizontal directions pushing on both sides pry loose the first layer while the substrate 216 is pulling upward. The substrate 216 may be permanently bonded or removably bonded to the first layer 222. Removable bonding may be accomplished by various bonding and handling techniques including but not limited to adhesives, waxes, and vacuum handlers.

This methods illustrated in FIG. 2A-F, may be facilitated with knowledge of separation characteristics between layers, for example, with known imaging techniques such as AFM and STM. This information, along with well know tools to move the knife edges with sub-angstrom precision, allows for reliable separation of a predetermined number of desired layers, or a single layer.

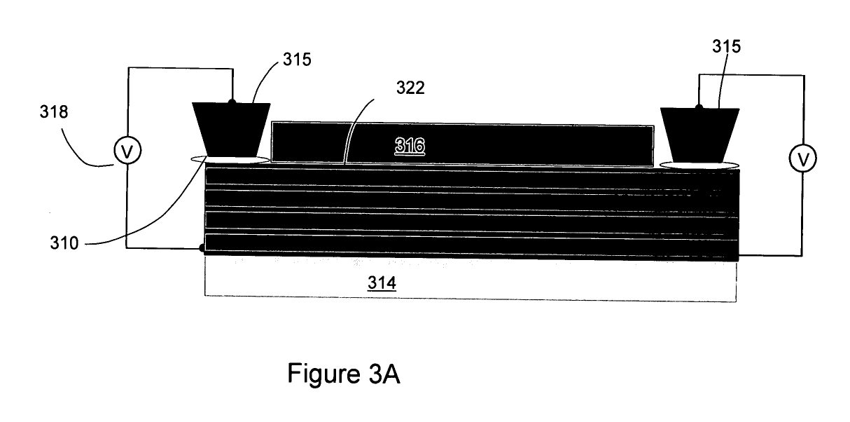

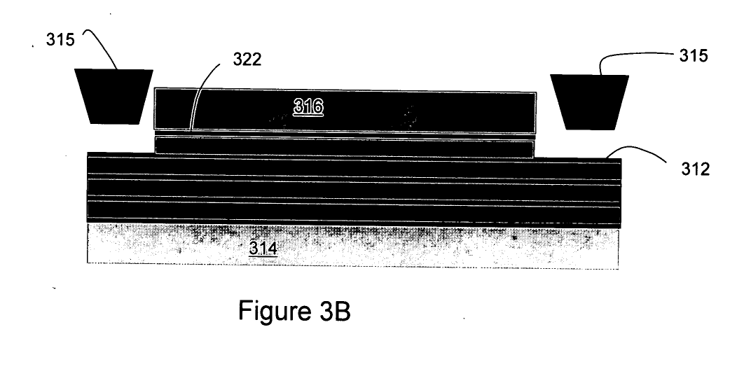

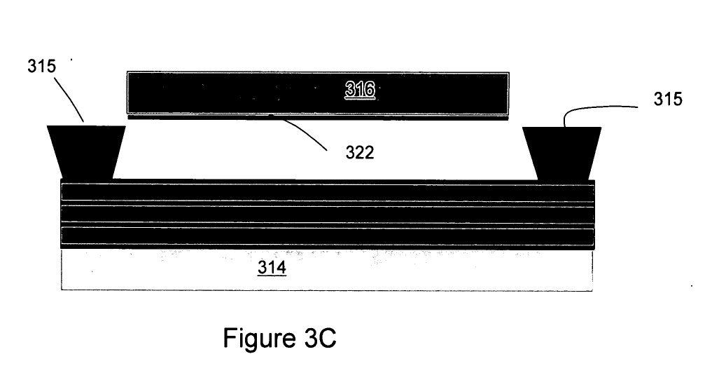

FIG. 3A-C illustrates yet another embodiment to reliably separate a predetermined number of desired layers, or a single layer. It exploits etching the peripheral regions of the first layer 310 to expose the second layer by known etching techniques including electrochemical etching, as shown in FIG. 3A. Note that one may etch to expose a third, fourth, or N^{th} layer thereby allowing for removal of a selected predetermined number of layers, for example, in combination with methods described in FIG. 2A-F above to allow for the selection and the removal of more than a single layer. Further, a voltage source 318 may be applied across electrodes 315, that are contacting the peripheral regions 310, of the first layer 322, to electrochemically etch the desired surface. Alternatively, other etching techniques such as chemical etching and sputter etching may be employed.

After the etching is complete, the exposed second layer 312 is pushed as in FIG. 3B, whereby the electrodes 315 (or another mechanical structure) push down on the second layer and subsequent layers optionally against a substrate 314 while the top substrate 316 permanently or removably bonded to the first layer 322 is pulled upward. Thus a single layer (or a predetermined number of layers) may be conveniently and inexpensively removed and optionally transferred to a third substrate.

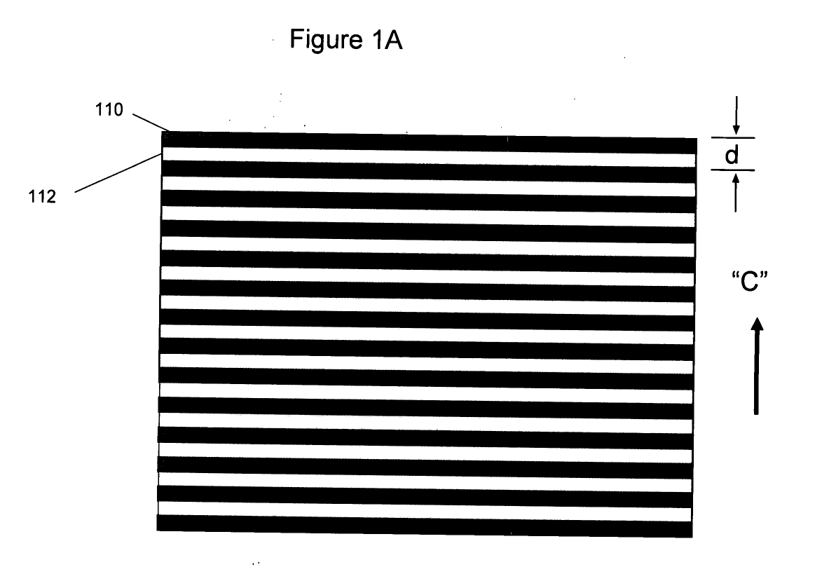

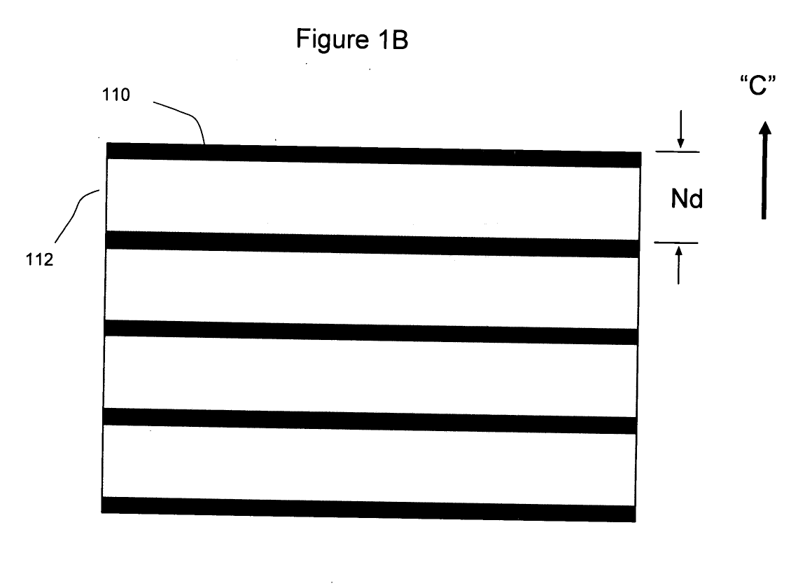

The substrate 316 is removably bonded to the first layer 322 by many bonding and handling techniques including but not limited to adhesives, waxes, and vacuum handlers. The final result in 3C may be repeated for all the other layers of the lamellar material until all layers are removed with minimum of waste. This method can also be combined with method described in FIG. 2A-F above to allow for the selection and the removal of more than a single layer. For instance, in the case of graphene, it may be desirable to have a single layer of 1 Angstrom, 2 layers of 2 Angstroms or, N layers of multiple Angstroms, depending on how the graphite is exfoliated to swell the interlayer spacing by factors of 10-1,000. (See exfoliated graphite description presented above with respect to FIGS. 1A and 1B).

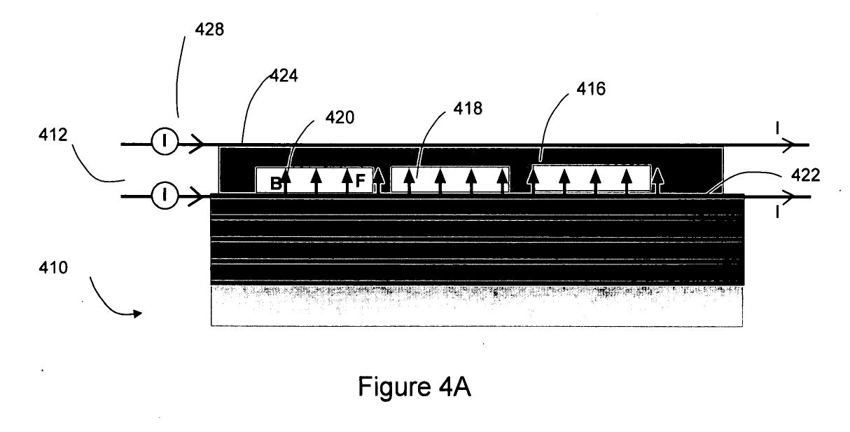

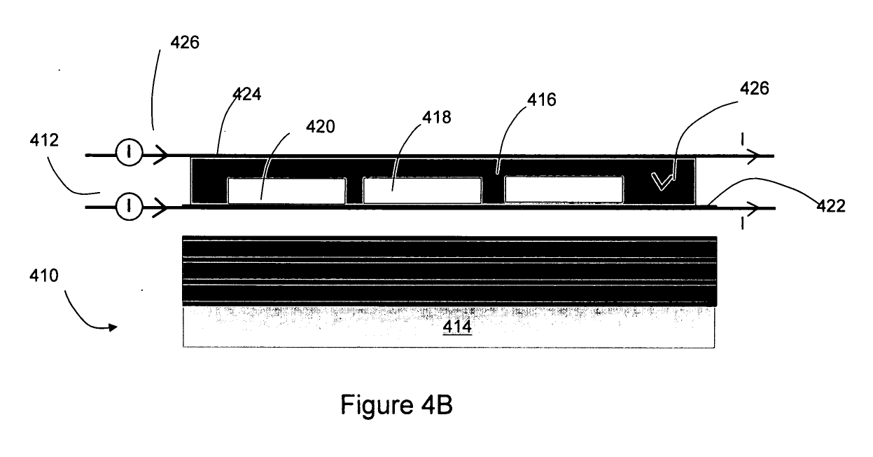

Another embodiment that takes advantage of the unique properties of graphene and other metallically coated lamellar materials is described in FIG. 4A-B. A special substrate 416 is provided and is removable attached to the first layer 422 intended for removal. Current 428 from a current source 412 is applied to the first graphene layer 422 and electrode 424 deposited on top of substrate 416. The current 428 flowing in electrode 424 and flowing out (in the opposite direction) of single layer 422 result in a magnetic force 420 that selectively pulls upward in the upward direction 418 the first layer 422. This advantageously utilizes the natural electrically conductive nature of lamellar materials such as graphene, that is, wherein the material exhibits a higher electrically conductivity along the surface or planar direction thereof as compared to across the thickness of lamellar materials. By further applying a mechanical force upward to substrate 416, the combination of magnetic and mechanical forces allows peeling with ease of layer 422. Since no such forces are influencing second and third layers, they are left intact. The separation process is illustrated in FIGS. 4A-B. Furthermore, in combination with various other techniques described herein, the method and system of FIGS. 4A and 4B may be employed to enhance the separation, or reduce the interlayer bond strength, to allow removal of a predetermined number of layers of lamellar material.

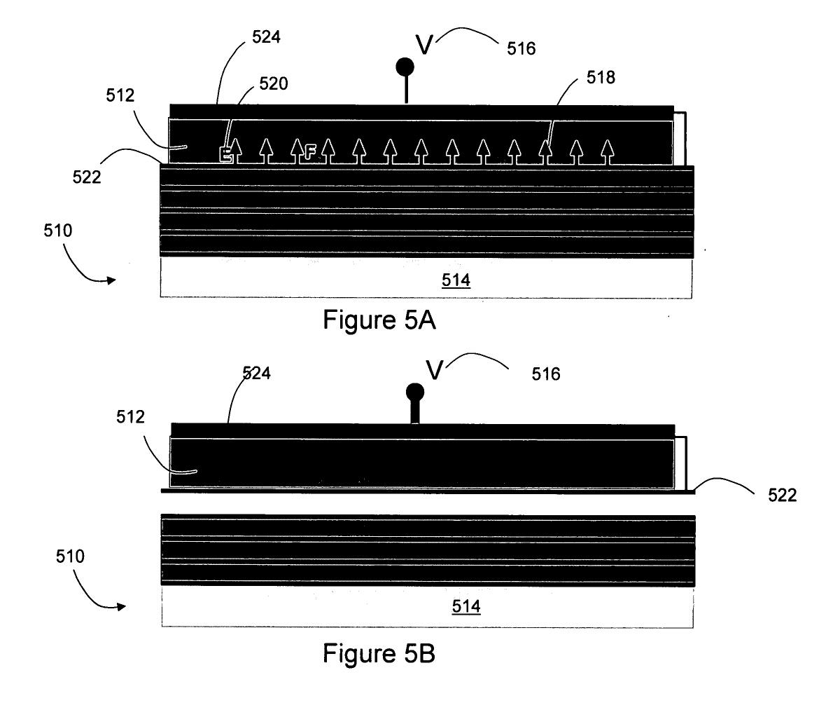

Instead of exploiting the magnetic force in the aforementioned embodiment, it is possible to use instead electrostatic force as illustrated in FIGS. 5A-B. In this case a voltage source 516 is applied to electrode 524, deposited on substrate 512 and a revealed portion of the first layer 522. The electric field 520 is applied and causes an electrostatic force in the upward direction 518, and along with a mechanical force applied to a substrate upward in a pulling selection, the first layer is selectively removed from the entire multi layer structure 510. Furthermore, in combination with various other techniques described herein, the method and system of FIGS. 5A and 5B may be employed to enhance the separation, or reduce the interlayer bond strength, to allow removal of a predetermined number of layers of lamellar material.

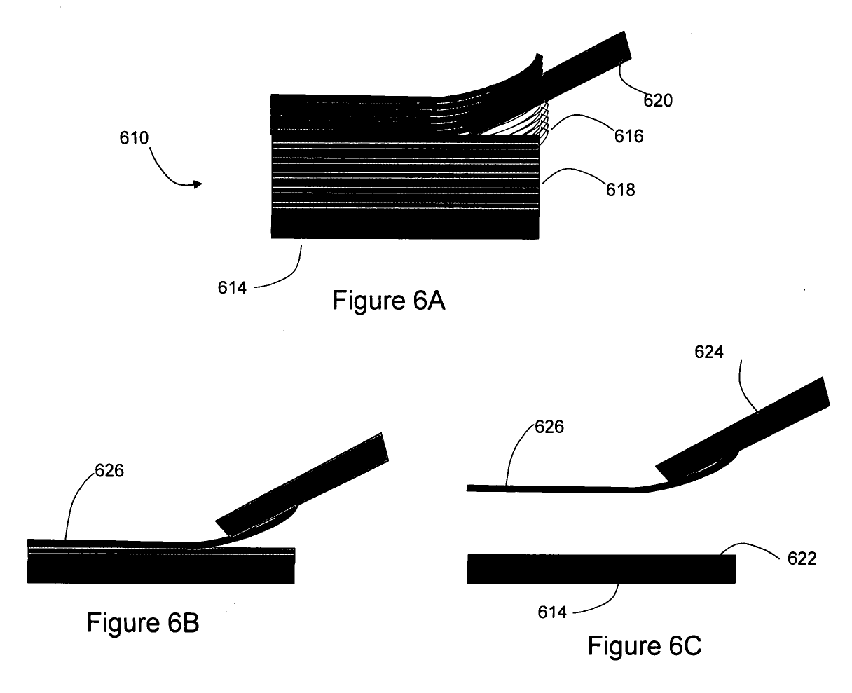

681 Another embodiment of peeling layers of lamellar material is shown in FIGS. 6A-C. Here the multilayer lamellar structure 610 is attached to a substrate 614 to the bottom while at the top implement substrate 612 is removably attached to the top of the specimen. Said substrate 612 may be a vacuum handler, adhesive tapes or other films with removable adhesives. The first step is to lift substrate 612 which will pull or peel a random number of layers 616, shown in FIG. 6A. This process is repeated as necessary until the last few layers remain as in FIG. 6B. In FIG. 6C the second to last layer is finally removed, leaving the last layer 622 bonded to substrate 614. Note that the shavings, or the peelings of random number of layers are in turn attached to substrate 614 and the process is repeated until the desired number of single layers are removed and utilized.

The above embodiments of methods to selectively remove single layers, or predetermined number of layers from lamellar could be combined as appropriate to achieve most advantageous, practical and economical way to produce the desired results.

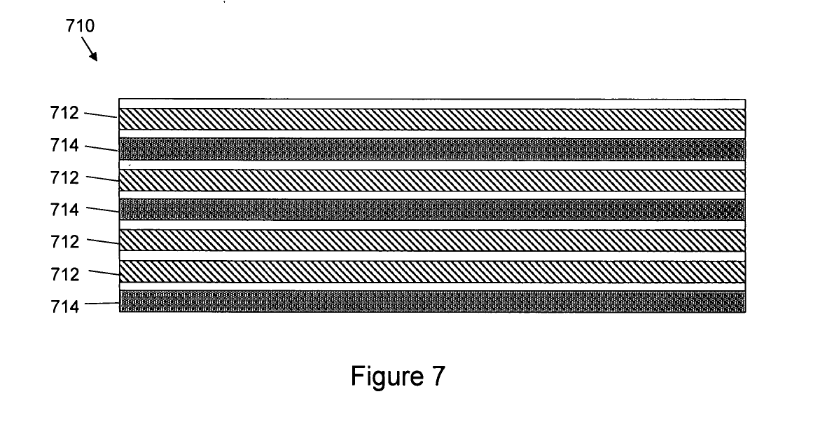

Referring now to FIG. 7, it is shown that by controlling the number of atomic layers, it is possible to stack predetermined numbers of atomic layers of various types of material to provide a heterogeneous lamellar structure. For example, a composite material 710 may be provided with certain layers of a first material 712 and certain layers of a second material 714. Note that one of the materials is one or more atomic layers derived from a lamellar material as described herein, and the other material may comprise, for example, another one or more atomic layers derived from a lamellar material as described herein, or other material including but not limited to one or more materials selected from the group consisting of insulating materials, semiconductor materials, oxides, superconductors, metals, magnetic materials, hydrides, GdMg, W03, MoO3, LiCoO2.

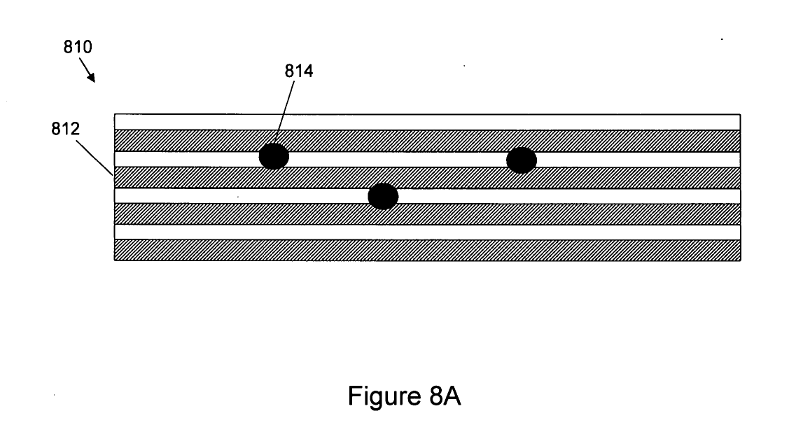

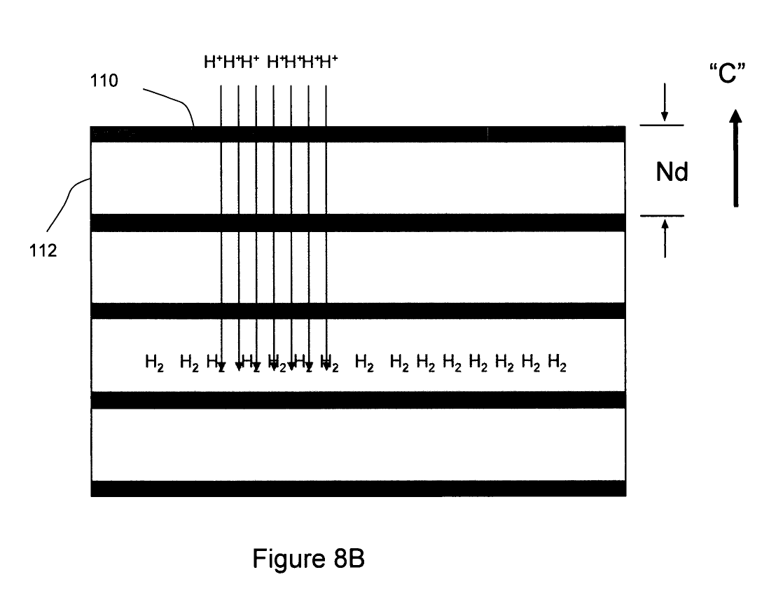

Referring now to FIG. 8A, it is shown that by controlling the number of atomic layers, it is possible to stack predetermined numbers of atomic layers and incorporate between certain layers various types of material to provide a composite structure 810 including the predetermined number of atomic layers 812 and the incorporated material 814. The incorporated material 814 may be introduced by various implantation techniques, including but not limited to implantation techniques wherein particles and or ions of the incorporated material 814 are accelerated or otherwise imparted with direct force to penetrate certain layers 812. Further, the incorporated material 814 may be introduced by various intercalation techniques, including but not limited to intercalation techniques so that the incorporated material 814 is inserted or interposed, for example, wherein the predetermined number of atomic layers 812 is disposed in a gas or liquid medium including material 814 is provided as a species mixed therein.

Referring to FIG. 8B, it is shown that the penetration depth of the implanted ions or other species may be tailored to various needs. For example, the energy level may differ depending on the desired depth, e.g., 50 eV to 100 eV to penetrate the 1st layer, 100 eV to 200 eV to penetrate the second layer, and so on.

In certain preferred embodiments, a narrow energy distribution is selected to achieve a narrow depth penetration or intercalation distribution species. This allows selection of a consistent depth, or number of layers penetrated.

Note that smaller energy doses may be required for embodiments of the present invention whereby graphene one of plural layers as compared to traditional semi-conductor material implantation methods. Since the van Der Walls forces between layers are very weak, smaller dosages (in terms of current and or voltage) is required.

In certain other embodiments of the present invention, a broad energy distribution, e.g., ranging from about 50 V to about 10 kV, is selected to selected to allow penetration intercalation of species over a number of layers. For example, such a composite, having penetrated catalytic species therethrough, may serve as an oxidation catalyst (including, for example, H+, Cs+, Li+, Na+, K+) for various cutting embodiments as described in co-pending application number 11/______, filed on the same date hereof, under Express Mail Label Number EV443782141US (Attorney Docket Number REVEO-0260USAAPN39), entitled “Method Of and System For Cutting Carbon Based Materials”, which is incorporated by reference herein. This penetration or intercalation further may take place starting from designated areas of an exposed surface of the lamellar material, thereby allowing for specific areas of a planar surface to be implanted, as shown in FIG. 8C, wherein the predetermined number of layers 810 (or a composite as described with respect to FIGS. 7, 8A, or 8B) have areas 880 (shown as thick white lines in the shape of rectangles with untreated regions in the interior of the rectangle) with material introduced therein, for example, as catalytic species to facilitate cutting to described in aforementioned co-pending application number 11/______, filed on the same date hereof, under Express Mail Label Number EV443782141US (Attorney Docket Number REVEO-0260USAAPN39), entitled “Method Of and System For Cutting Carbon Based Materials”, incorporated by reference herein.

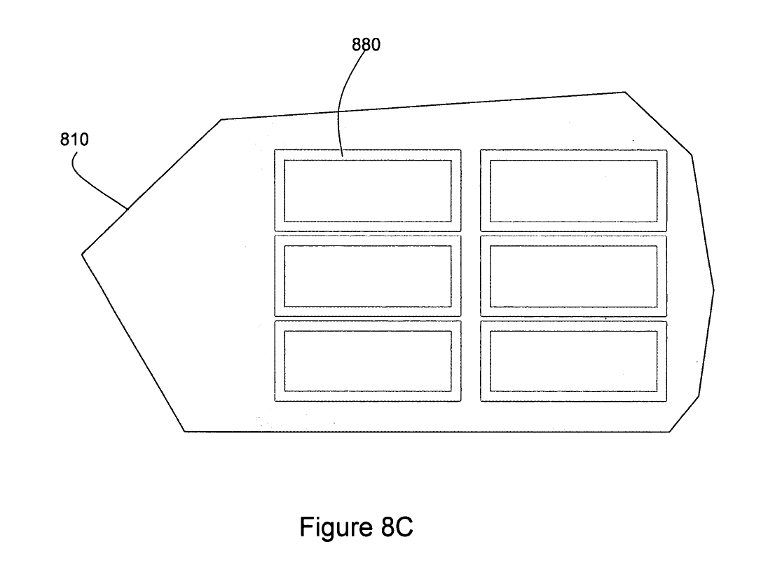

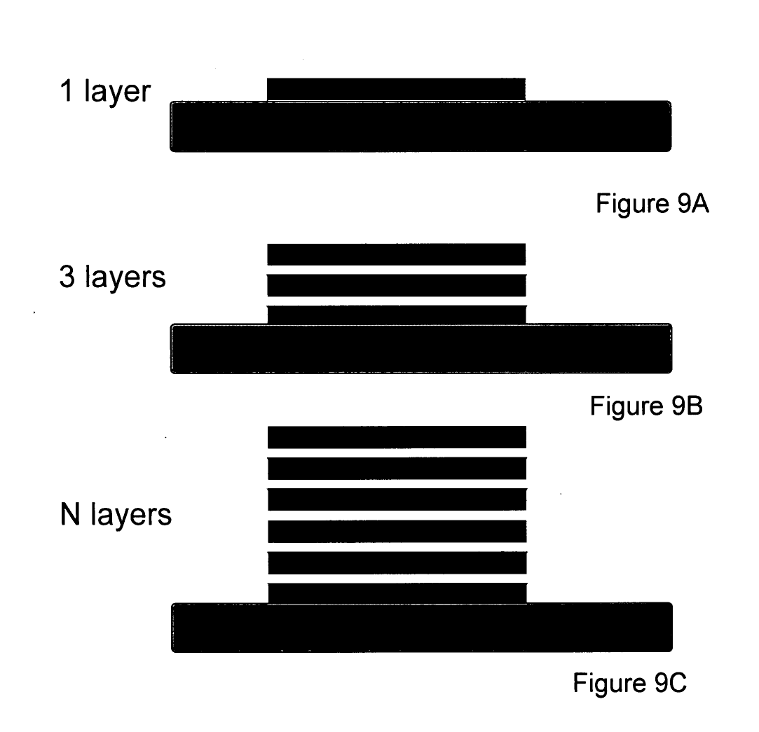

Referring now to FIGS. 9A-9C, it is shown that using the herein described methods, it is possible to isolate one layer (FIG. 9A), three layers (FIG. 9B), or any number N layers (FIG. 9C) of the lamellar material.

While preferred embodiments have been shown and described, various modifications and substitutions may be made thereto without departing from the spirit and scope of the invention. Accordingly, it is to be understood that embodiments of the present invention has been described by way of illustrations and not limitation.

1. A material comprising a predetermined number of one or more layers, said one or more layers being layers of a lamellar material that are weakly bonded to each other.

2. The material as in claim 1, wherein said lamellar material is selected from the group consisting of mica, WS2, MoS2, YBCO (yttrium barium copper oxide) and other related superconductors, NbSe2, Bi2Sr2CaCu2Ox, graphite, boron nitride, dichalcogenide, trichalcogenide, tetrachalcogenide, pentachalcogenide, double hydroxides, anionic clays and hydrotalcite-like materials.

3. The material as in claim 1, wherein the predetermined number of layers is one layer.

4. The material as in claim 1, wherein predetermined number of layers is 1 to about 100.

5. The material as in claim 1, wherein predetermined number of layers is about 100 to about 1000.

6. The material as in claim 1, wherein predetermined number of layers is greater than about 1000.

7. The material as in claim 1, wherein the predetermined number of layers are at least partially supported by a substrate.

8. The material as in claim 1, wherein the predetermined number of layers are permanently attached to at least a portion of a substrate.

9. The material as in claim 1, wherein the predetermined number of layers are removably attached to least a portion of a substrate.

10. The material as in claim 1, wherein the predetermined number of layers has a first outer surface and a second outer surface, wherein the first outer surface is permanently or removably attached to at least a portion of a first substrate and the second outer surface is permanently or removably attached to at least a portion of a second substrate.

11. The material as in claim 1, wherein the at least one layer is an atomic layer of carbon atoms.

12. The material as in claim 13, wherein the layer is a layer of graphene.

13. The material as in claim 1, wherein said layers of lamellar material are weakly bonded substantially by van der Waals forces.

14. The material as in claim 1, wherein said layers of lamellar material comprise atomic layers.

15. The material as in claim 1, wherein at least a portion of a surface of said material is atomically flat.

16. The material as in claim 1, wherein the at least one predetermined number of layers comprises a plurality a layers, wherein said plurality of layers is exfoliated.

17. The material as in claim 1, wherein the at least one predetermined number of layers comprises a plurality a layers of graphene, wherein said plurality of layers of graphene are exfoliated.

18. A composite material comprising the material of claim 1, wherein said at least one predetermined number of layers includes plural layers, and
at least one introduced atomic or molecular species.

19. The composite material as in claim 18, wherein said introduced atomic or molecular species is present at predefined depths between one or more of said plural layers.

20. The composite material as in claim 18, wherein said introduced atomic or molecular species is present at random depths between one or more of said plural layers.

21. The composite material as in claim 18, wherein said introduced atomic or molecular species is present at predefined areas of said material.

22. A composite material comprising the material of claim 1, and
at least one layer of another material.

23-147. (canceled)
